(19) United States
(12) Patent Application Publication
(10) Pub. No.: US 2003/0124841 A1
(43) Pub. Date: Jul. 3, 2003

(54) Method for fabricating semiconductor device

(76) Inventor: Soon-Yong Kweon, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 10/318,101

(22) Filed: Dec. 13, 2002

(30) Foreign Application Priority Data
Dec. 29, 2001 (KR) 2001-0087734

(51) Int. Cl. H01L 21/44

(52) U.S. Cl. 438/653; 438/655; 438/656; 438/660

(57) ABSTRACT

Provided is a method for forming a semiconductor device that can reduce contact resistance of a storage node contact connecting the source/drain of a transistor with a capacitor. The method includes the steps of: forming an inter-layer insulating layer on a silicon substrate, wherein a junction is formed on a surface of the silicon substrate; forming a contact hole exposing the junction by selectively etching the inter-layer insulating layer; removing a native silicon oxide layer on the junction by forming titanium layer on the junction; and forming a titanium silicide layer as a first ohmic contact layer on the junction by carrying out a first thermal treatment.

### FIELD OF THE INVENTION

The present invention relates to a method for fabricating a semiconductor device; and, more particularly, to a method for fabricating a capacitor.

### DESCRIPTION OF RELATED ART

Generally, researches have been carried out to develop a semiconductor device that can overcome the refresh limit of conventional dynamic random access memory (DRAM) devices and provide large memory capacity, using a ferroelectric thin film in the fabrication of a ferroelectric capacitor. As a sort of nonvolatile memory devices, a ferroelectric random access memory (FeRAM) device using the ferroelectric thin film can memorize stored data even when the power is off, and it can operate as fast as conventional DRAM. For this reason, FeRAM becomes to stand in the spotlight as a next-generation memory device.

Usually, such ferroelectric thin films as SrBi₂Ta₂O₉ (SBT) and Pb(Zr,Ti)O₃ (PZT) are used to store electricity in the FeRAM device. Since ferroelectric thin films have dielectric constants that go hundreds to thousands and have two stable remnant polarization (Pr) statues at room temperature, researchers are developing a method for fabricating a ferroelectric thin film to apply it to a nonvolatile memory device. A nonvolatile memory device using a ferroelectric thin film makes use of the hysteresis effect, in which signals are inputted by controlling the polarization direction in the direction of the electric field applied thereto, and then when the electric field is withdrawn, digital signals ‘1’ and ‘0’ remain stored.

Recently, most studies are carried out to develop a method for lowering the temperature of the thermal treatment for crystallizing a ferroelectric film and a method for forming a plug that can endure high temperature thermal treatment.

A conventional method for fabricating a high density FeRAM is described hereinafter.

FIGS. 1A though 1C are cross-sectional views showing a method for fabricating a ferroelectric capacitor according to a prior art. Referring to FIG. 1A, a field oxidation layer 12 is formed on a semiconductor substrate 11 to separate the elements of the substrate. Then, a junction 13, such as source/drain of a transistor, is formed by ion-injecting impurities into the active region of the semiconductor substrate 11, and an inter-layer dielectric (ILD) 14 is formed on the semiconductor substrate 11. Here, the junction 13 is either p-type or n-type.

Subsequently, a photoresist is coated on the ILD 14 and patterned by performing light-exposure or development, and then a storage node contact holes 15 are formed to expose part of the surface of the junction 13 by using the patterned photoresist (not shown) as a mask and etching the ILD 14. Here, a natural oxidation layer 16 is formed on the surface of the junction 13, which is exposed after the formation of the storage node contact holes 15.

Referring to FIG. 1B, a polysilicon layer is deposited on the ILD 14 until the storage node contact holes 15 are filled up, and then polysilicon plugs 17 are formed filling the storage node contact holes 15 by performing chemical mechanical polishing (CMP) on the polysilicon layer until the surface of the ILD 14 is exposed.

Subsequently, a titanium silicide 18 is formed on the polysilicon plugs 15, by depositing titanium (Ti) on the entire surface and performing thermal treatment. The thermal treatment induces the reaction between the titanium atoms and the silicon atoms on the polysilicon plugs 17.

Here, the titanium silicide 18 forms an ohmic contact between the polysilicon plugs 17 and the bottom electrode, which will be formed later. The un-reacted titanium is removed after the formation of the titanium silicide 18.

After all, the storage node contact (SNC), in which the polysilicon plug 17 and the titanium silicide 18 are deposited in order, is connected to the junction 13 through the storage node contact hole 15 (of FIG. 1A).

Referring to FIG. 1C, a deposition structure of a titanium nitride (TiN) 19 and bottom electrodes 20 are formed on the ILD 14 including the titanium silicide 18, and then a planar second ILD 21 is formed to expose the upper surface of the deposition structure and surround its sides.

The second ILD 21 that surrounds the deposition structure of the titanium nitride 19 and the bottom electrodes 20 is formed by depositing the titanium nitride 19 and the bottom electrodes 20 sequentially, patterning them simultaneously to form a deposition structure, depositing the second ILD 21 on the entire surface including the deposition structure, and performing chemical mechanical polishing on the second ILD 21 until the surface of the deposition structure is exposed. Here, the titanium nitride 19 is a barrier layer for preventing reciprocal diffusion between the polysilicon plug 17 and the bottom electrode 20.

Subsequently, a ferroelectric film 22 and a top electrode 23 are formed to form a ferroelectric capacitor along with the bottom electrode 20 already formed on the planar second ILD 21.

In the conventional method described above, the plugs are formed of polysilicon to form a high density FeRAM, and the titanium silicide 18 and the titanium nitride 19 are formed on the polysilicon plug 17 to reduce contact resistance between the polysilicon plug 17 and the bottom electrode 20.

However, this structure of the conventional method has a problem that it increases contact resistance, because a thin (<50 Å) silicon oxide layer (SiO₂), which is a natural oxide layer, is formed naturally between the polysilicon plug 17 and the junction 13 and it fails perfect ohmic contact. This is because the plugs are not filled with polysilicon right after the storage node contact holes 15 are formed. That is, after the formation of the storage node contact holes 15, when the semiconductor substrate is exposed to atmosphere for a predetermined time to deposit polysilicon, a natural oxide layer is formed on the surface of the junction 13. To suppress the formation of the natural oxide layer instrumentally, etching equipment for forming the storage node contact holes 15 and deposition equipment for depositing polysilicon should be incorporated together so that the two processes could be performed directly in vacuum, which is almost impossible in reality. Besides FeRAM, DRAM having a plug structure also has the same problem.

### SUMMARY OF THE INVENTION

It is, therefore, an object of the present invention to provide a method for fabricating a semiconductor device that can reduce contact resistance of storage node contacts connecting a source/drain of transistor and a bottom electrode.

In accordance with an aspect of the present invention, there is provided a method for fabricating a semiconductor device, including the steps of: forming an inter-layer insulating layer on a silicon substrate, wherein a junction is formed on a surface of the silicon substrate; forming a contact hole exposing the junction by selectively etching the inter-layer insulating layer; removing a native silicon oxide layer on the junction by forming titanium layer on the junction; and forming a titanium silicide layer as a first ohmic contact layer on the junction by carrying out a first thermal treatment.

In accordance with another aspect of the present invention, there is provided a method for fabricating a semiconductor device, including the steps of: forming an inter-layer insulating layer on a silicon substrate, wherein a junction is formed on a surface of the silicon substrate; forming a contact hole exposing the junction by selectively etching the inter-layer insulating layer; removing a native silicon oxide layer on the junction by forming titanium layer on the junction and the inter-layer insulating layer; forming a polysilicon layer on the titanium layer; forming a first titanium silicide layer as a first ohmic contact layer on the junction by carrying out a first thermal treatment and simultaneously forming a second silicide layer on the inter-layer insulating layer; and forming a plug in the contact hole by removing the polysilicon layer and the second silicide layer until the inter-layer insulating layer, wherein the plug is formed with the first titanium silicide layer on the juction, the polysilicon layer on the first titanium silicide layer and the second titanium silicide layer on sidewalls of the contact hole.

### BRIEF DESCRIPTION OF THE DRAWINGS

The above and other objects and features of the present invention will become apparent from the following description of the preferred embodiments given in conjunction with the accompanying drawings, in which:

FIGS. 1A though 1C are cross-sectional views showing a method for fabricating a ferroelectric capacitor according to a prior art;

FIGS. 2A though 2D are cross-sectional views describing a method for fabricating a ferroelectric capacitor in accordance with a first embodiment of the present invention; and

FIGS. 3A through 3D are cross-sectional views describing a method for fabricating a ferroelectric capacitor in accordance with a second embodiment of the present invention.

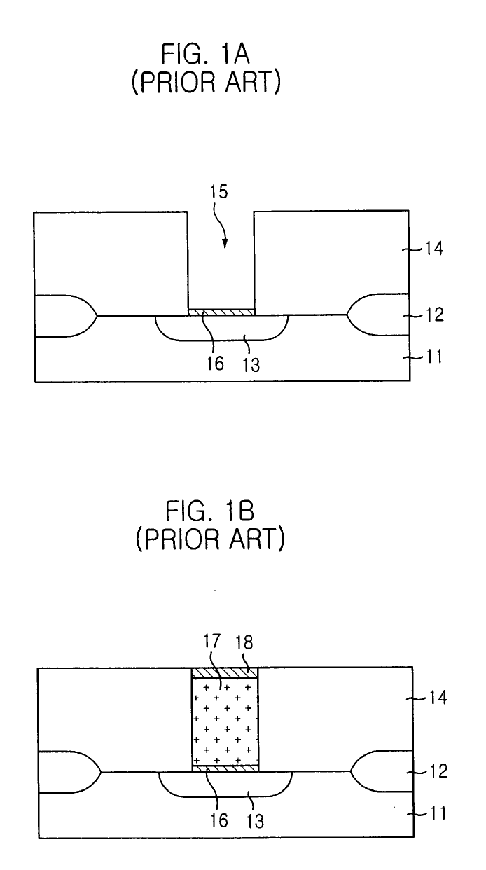

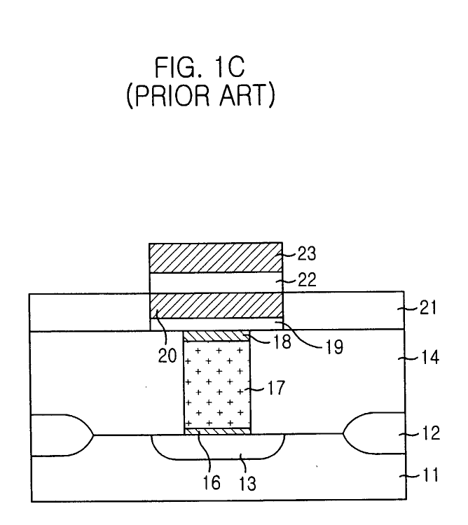

### DETAILED DESCRIPTION OF THE INVENTION

Other objects and aspects of the invention will become apparent from the following description of the embodiments with reference to the accompanying drawings, which is set forth hereinafter.

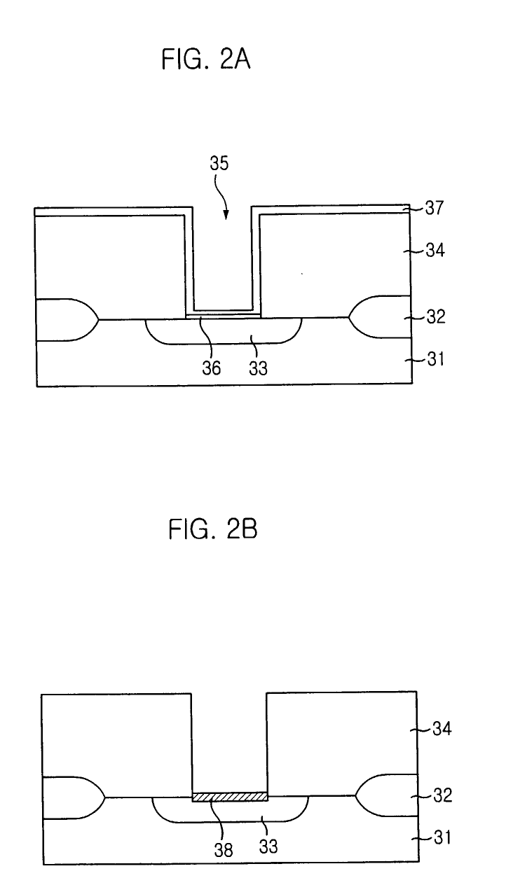

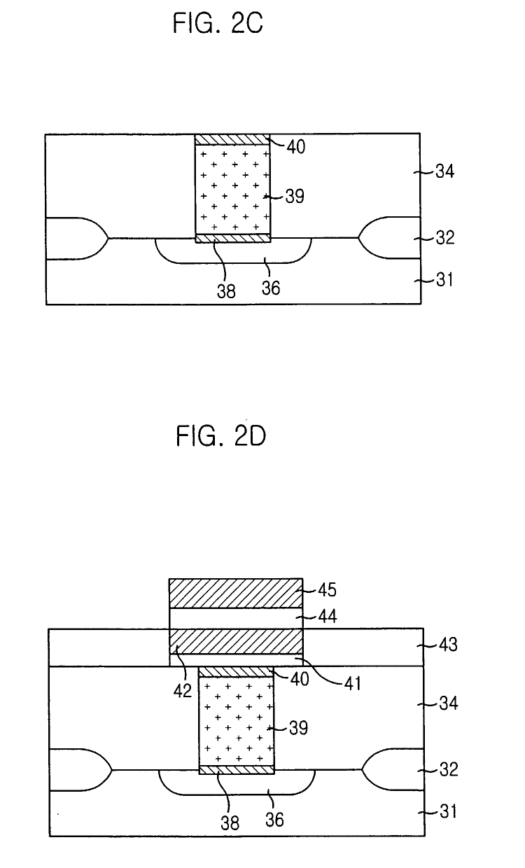

FIGS. 2A though 2D are cross-sectional views describing a method for fabricating a ferroelectric capacitor in accordance with a first embodiment of the present invention.

Referring to FIG. 2A, a field oxidation layer 32 is formed on a semiconductor substrate 31 to separate the elements of the substrate. Then, a junction 33, such as source/drain of a transistor, is formed by ion-injecting impurities into the active region of the semiconductor substrate 31, and an inter-layer dielectric (ILD) 34 is formed on the semiconductor substrate 31. Here, the junction 33 is either p-type or n-type, and transistors, word lines and bit lines have been formed prior to the formation of the ILD 34.

Subsequently, a photoresist is coated on the ILD 34 and patterned by performing light-exposure or development, and then a storage node contact holes 35 are formed to expose part of the surface of the junction 33 by using the patterned photoresist (not shown) as a mask and etching the ILD 34. Here, a silicon oxide 36, which is a natural oxidation layer, is formed on the surface of the junction 33 exposed after the formation of the storage node contact holes 35.

Subsequently, a titanium layer 37 is deposited on the entire surface of the resultant structure to remove the silicon oxide 36, the natural oxide layer. Since titanium has strong chemical attraction to oxygen, compared to silicon, the silicon oxide is decomposed. This way, the silicon oxide 36 formed on the junction 33 can be removed in the subsequent process.

Meanwhile, the titanium layer 37 is deposited in a chemical vapor deposition (CVD), atomic layer deposition (ALD), or physical vapor deposition (PVD) method. Especially, as for PVD, an ionized metal plasma (IMP) or collimator method is used.

The titanium layer 37 is deposited in a thickness of 10˜200 Å at a temperature of room temperature about 500° C.

Referring to FIG. 2B, a first titanium silicide 38 is formed on the junction 33 by performing a thermal process and inducing silicide reaction between the silicon atoms of the junction 33 and the titanium atoms of the titanium layer 37. The un-reacted titanium layer is removed by cleaning with a chemical cleaner, which is SC-1 (NH₄OH:H₂O₂:H₂O=1:4:20).

The first titanium silicide 38 formed from the thermal treatment includes a predetermined amount of titanium oxide (TiOₓ). This is because the titanium layer 37 decomposes the silicon oxide 36, and the decomposed silicon participates the reaction generating the first titanium silicide 38 and the oxygen broken away from the silicon oxide 36 forms titanium oxide with titanium. Here, since the titanium oxide exists in the first titanium silicide 38 discontinuously, it hardly affects ohmic contact resistance.

Meanwhile, to form the first titanium silicide 38, rapid thermal process (RTP) or furnace annealing is performed on the titanium layer 37. The RTP is carried out at a temperature of 600˜1,000° C. in the ambient of argon or nitrogen without oxygen for 1˜10 seconds. The furnace annealing is carried out at a temperature of 600˜1,000° C. in the ambient of argon or nitrogen without oxygen for ten minutes to two hours.

Referring to FIG. 2C, a polysilicon layer is deposited on the ILD 34 until the storage node contact holes 35 having the first titanium silicide 38 formed therein are filled up. Then, polysilicon plugs 39 are formed being buried in the storage node contact holes 35 by performing chemical mechanical polishing (CMP) or etch-back until the surface of the ILD 34 is exposed.

Subsequently, a titanium layer is deposited on the entire surface again, and then a second titanium silicide 40 is formed on the polysilicon plugs 39 by performing a thermal treatment under the same conditions as the first titanium silicide 40 is formed, and thus inducing the reaction between the silicon atoms of the polysilicon plugs 39 and the titanium atoms.

Accordingly, the first titanium silicide 38 is formed between the polysilicon plugs 39 and the junction 33, and the second titanium silicide 40 is formed between the polysilicon plug 39 and bottom electrode, which will be formed later.

Meanwhile, after the formation of the second titanium silicide 40, the un-reacted titanium layer is removed with chemical cleaner, which is SC-1 (NH₄OH:H₂O₂:H₂O=1:4:20). Here, different from the first titanium silicide 38, the second titanium silicide 40 formed from the thermal treatment does not contain titanium oxide (TiOₓ).

Referring to FIG. 2D, after the formation of a deposition structure, where a titanium nitride 41 and bottom electrodes 42 are deposited in order on the ILD 34 including the second titanium silicide 40, a planar second ILD 43 is formed to expose the surface of the deposition structure and surround its sides.

Here, the second ILD 43 that surrounds the deposition structure of the titanium nitride 41 and the bottom electrodes 42 is formed by deposing the titanium nitride 41 and the bottom electrodes 42 sequentially, patterning them simultaneously to form the deposition structure, depositing the second ILD 43 on the entire surface of the deposition structure, and performing CMP on the second ILD 43 until the surface of the deposition structure is exposed.

Subsequently, a ferroelectric film 44 and a top electrode 45 are formed on the second ILD 43 to form a ferroelectric capacitor along with the bottom electrodes 42 formed already. Here, for the ferroelectric film 44, SBT, SBTN, PZT or BLT can be used. The thickness of the ferroelectric film 44 is 50˜2,000 Å, and as a deposition method, spin-on, PVD, CVD, ALD, or metal organic deposition (MOD) can be used.

After the deposition of the ferroelectric film 44, thermal treatment is carried out conventionally to crystallize it. It is performed at a temperature of 400˜800° C. for ten minutes to five hours in the ambient of any one selected from the group composed of O₂, N₂, Ar, O₃, He, Ne and Kr.

In the first embodiment described above, high density FeRAM devices are embodied by using a storage node contact, where the first titanium silicide 38, polysilicon plug 39, second titanium silicide 40 are deposited in order, to connect the junction 33 with the bottom electrode 42, and the ohmic contact resistance of the storage node contacts is decreased by removing silicon oxide between the junction 33 and the polysilicon plug 39 and forming the first titanium silicide 38.

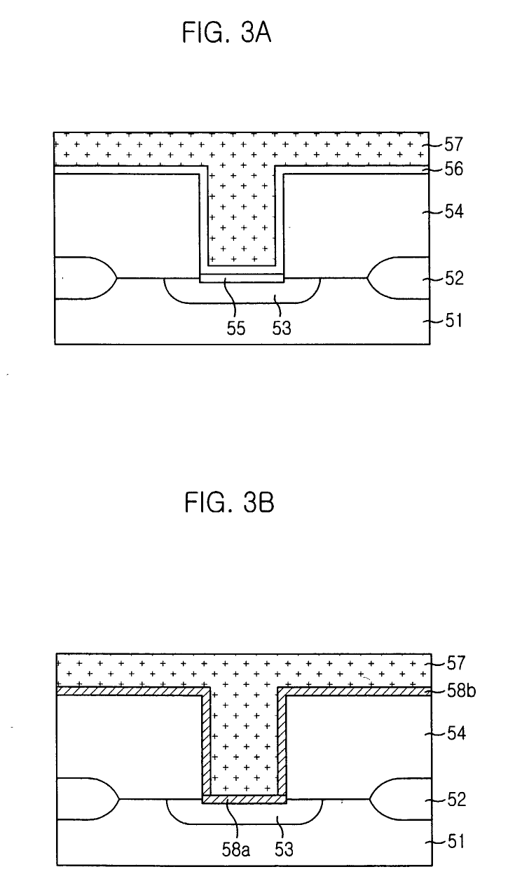

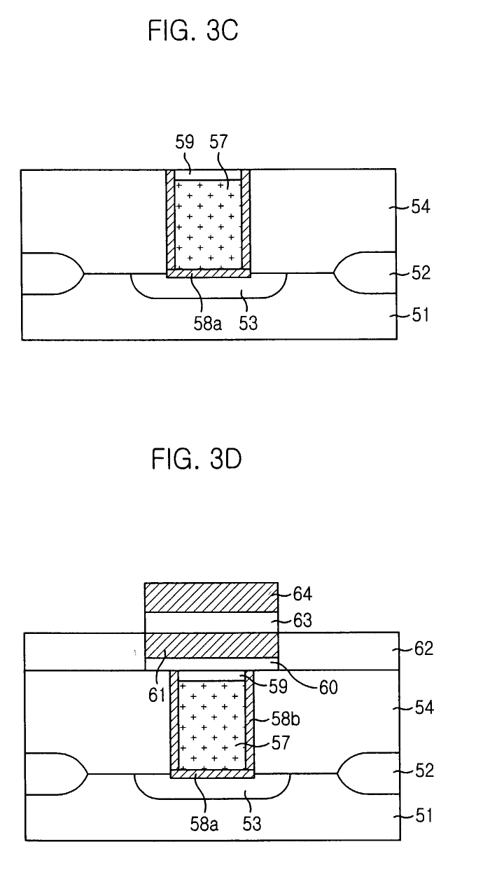

FIGS. 3A through 3D are cross-sectional views describing a method for fabricating a ferroelectric capacitor in accordance with a second embodiment of the present invention.

Referring to FIG. 3A, a field oxidation layer 52 is formed on a semiconductor substrate 51 to separate the elements of the substrate. Then, a junction 53, such as source/drain of a transistor, is formed by ion-injecting impurities into the active region of the semiconductor substrate 51, and an ILD 54 is formed on the semiconductor substrate 51. Here, the junction 53 is either p-type or n-type, and transistors, word lines and bit lines have been formed prior to the formation of the ILD 54.

Subsequently, a photoresist is coated on the ILD 54 and patterned by performing light-exposure or development, and then a storage node contact holes (not shown) are formed to expose part of the surface of the junction 53 by using the patterned photoresist (not shown) as a mask and etching the ILD 34. Here, a silicon oxide 55, which is a natural oxidation layer, is formed on the surface of the junction 53 exposed after the formation of the storage node contact holes, as the junction 53 is exposed to the atmosphere.

Subsequently, a titanium layer 56 is deposited on the entire surface of the resultant structure where the silicon oxide 55 is formed, and then a polysilicon layer 57 is deposited on the titanium layer 56 until the storage node contact holes are filled up completely.

Here, the titanium layer 56 is deposed to remove the natural oxidation layer, i.e., the silicon oxide 55, because titanium has strong chemical attraction to oxygen compared to silicon, the silicon oxide is decomposed. This way, the silicon oxide 55 formed on the junction 53 can be removed in the subsequent process.

Meanwhile, the titanium layer 56 is deposited in a CVD, ALD, or PVD method. Especially, as for PVD, an ionized metal plasma (IMP) or collimator method is used.

The titanium layer 37 is deposited in a thickness of 10˜200 Å at a temperature of room temperature ˜500° C.

Referring to FIG. 3B, a titanium silicide 58a is formed on the junction 53 by performing a thermal process and inducing silicide reaction between the silicon atoms of the junction 53 and the titanium atoms of the titanium layer 56, and then a titanium silicide 58b is formed on the surface of the polysilicon layer 57 that contacts the titanium layer 56 by inducing silicide reaction between the silicon atoms of the polysilicon layer 57 and the titanium atoms of the titanium layer 56.

Here, the titanium silicide 58a contains a predetermined amount of titanium oxide (TiOₓ) generated by the decomposition of the silicon oxide 55, and the titanium silicide 58a is pure titanium silicide.

The reason the titanium silicide 58a contains titanium oxide (TiOₓ) is because the titanium layer 56 decomposes the silicon oxide 55, and the decomposed silicon participates the reaction generating the titanium silicide 58a and the oxygen broken away from the silicon oxide 55 forms titanium oxide with titanium. Here, since the titanium oxide exists in the titanium silicide 58a discontinuously, it hardly affects ohmic contact resistance.

Meanwhile, to form the titanium silicide 58a or 58b, rapid thermal process (RTP) or furnace annealing is performed on the titanium layer 55. The RTP is carried out at a temperature of 600˜1,000° C. in the ambient of argon or nitrogen without oxygen for 1˜10 seconds. The furnace annealing is carried out at a temperature of 600˜1,000° C. in the ambient of argon or nitrogen without oxygen for ten minutes to two hours.

Referring to FIG. 3C, by removing the polysilicon layer 57 on the surface of the ILD 54 except that of the storage node contact hole in a CMP method, the polysilicon plug 57a in the storage node contact hole is maintained. Here, since the titanium silicide 58b on the ILD 54 is polished out together, the titanium silicide 58b comes to have a shape surrounding the polysilicon plug 57a, which is buried in the storage node contact hole.

Subsequently, a titanium layer is deposited on the entire surface again, and then a titanium silicide 59 is formed on the polysilicon plugs 57a by performing a thermal treatment under the same conditions as the titanium silicide 58a and 58b are formed, and thus inducing the reaction between the silicon atoms of the polysilicon plugs 57a and the titanium atoms.

In short, the titanium silicide 58a containing a predetermined amount of titanium oxide is formed between the polysilicon plugs 57a and the junction 53, and on the sidewalls of the storage node contact hole filled with the polysilicon plug 57a, the titanium silicide 58b which is pure titanium silicide is formed, and between the polysilicon plugs 57a and bottom electrodes, which will be formed later, the titanium silicide 59 is formed.

Meanwhile, after the formation of the titanium silicide 59, the un-reacted titanium layer is removed with chemical cleaner, which is SC-1 (NH₄OH:H₂O₂:H₂O=1:4:20). Here, different from the titanium silicide 58a, the titanium silicide 59 formed from the thermal treatment does not contain titanium oxide (TiOₓ).

Referring to FIG. 3D, after the formation of a deposition structure, where a titanium nitride (TiN) 60 and bottom electrodes 61 are deposited in order on the ILD 54 including the titanium silicide 59, a planar second ILD 62 is formed to expose the surface of the deposition structure and surround its sides.

Here, the second ILD 62 that surrounds the deposition structure of the titanium nitride 60 and the bottom electrodes 61 is formed through the same process as the first embodiment.

Subsequently, a ferroelectric film 62 and a top electrode 64 are formed on the second ILD 62 to form a ferroelectric capacitor along with the bottom electrodes 61 formed already on the planar second ILD 62. Here, for the ferroelectric film 63, SBT, SBTN, PZT or BLT can be used. The thickness of the ferroelectric film 63 is 50˜2,000 Å, and as a deposition method, spin-on, PVD, CVD, ALD, or MOD can be used.

After the deposition of the ferroelectric film 63, thermal treatment is carried out conventionally to crystallize it. It is performed at a temperature of 400˜800° C. for ten minutes to five hours in the ambient of any one selected from the group composed of O₂, N₂, Ar, O₃, He, Ne and Kr.

Different from the first embodiment, in this second embodiment described above, the titanium layer 56 is deposited and through the deposition of the polysilicon layer 57 and subsequent thermal treatment, the titanium silicide 58a is formed. However, the second embodiment brings the same effect as the first embodiment.

That is, high density FeRAM devices are embodied by using a storage node contact, where the titanium silicide 58a, polysilicon plug 57a, titanium silicide 59 are deposited in order, to connect the junction 53 with the bottom electrodes 61, and the ohmic contact resistance of the storage node contacts is decreased by removing the silicon oxide between the junction 53 and the polysilicon plug 57a and forming the titanium silicide 58a.

Although the first and second embodiments use titanium silicide as an ohmic contact layer, the same effect can be obtained, when tantalum silicide is used instead. Here, the process condition for forming tantalum silicide is the same as the process condition for forming titanium silicide.

The method of the present invention can be applied not only to capacitors having plugs and multi-layers, but to those having concaves or cylinders, as well as DRAM capacitors having plugs and multi-layers, concaves, or cylinders.

Also, this method can be applied to a capacitor, in which titanium nitride, which is the barrier layer, is buried within the storage node contact hole. That is, even when the storage node contact, where polysilicon plug, titanium silicide and titanium nitride are deposited in order, is buried in the contact hole, it is still possible to form ohmic contact by forming titanium silicide between the polysilicon plug and junction.

As described above, the method of the present invention improves the operation rate of a semiconductor device by reducing contact resistance of a storage node contact, and increase throughout of the device by enhancing signal discrimination, thus securing excellent characteristics of a semiconductor device.

While the present invention has been described with respect to certain preferred embodiments, it will be apparent to those skilled in the art that various changes and modifications may be made without departing from the scope of the invention as defined in the following claims.

What is claimed is:

1. A method for fabricating a semiconductor device, comprising the steps of:
forming an inter-layer insulating layer on a silicon substrate, wherein a junction is formed on a surface of the silicon substrate;
forming a contact hole exposing the junction by selectively etching the inter-layer insulating layer;
removing a native silicon oxide layer on the junction by forming titanium layer on the junction; and
forming a titanium silicide layer as a first ohmic contact layer on the junction by carrying out a first thermal treatment.

2. The method as recited in claim 1, further comprising the steps of:
forming a polysilicon plug in the contact hole;
forming a metal layer on the polysilicon plug; and
forming a silicide layer as a second ohmic contact layer on the polysilicon plug by carrying out a second thermal treatment.

3. The method as recited in any one of claim 2, wherein the first and the second thermal treatments is carried out at a temperature of 600˜1,000° C.

4. The method as recited in claim 2, wherein the metal layer tantalum, and the silicide layer is a tantalum silicide layer.

5. The method as recited in claim 1, wherein TiOₓ is contained in the titanium silicide layer.

6. A method for fabricating a semiconductor device, comprising the steps of:
forming an inter-layer insulating layer on a silicon substrate, wherein a junction is formed on a surface of the silicon substrate;
forming a contact hole exposing the junction by selectively etching the inter-layer insulating layer;
removing a native silicon oxide layer on the junction by forming titanium layer on the junction and the inter-layer insulating layer;
forming a polysilicon layer on the titanium layer;
forming a first titanium silicide layer as a first ohmic contact layer on the junction by carrying out a first thermal treatment and simultaneously forming a second silicide layer on the inter-layer insulating layer; and
forming a plug in the contact hole by removing the polysilicon layer and the second silicide layer until the inter-layer insulating layer, wherein the plug is formed with the first titanium silicide layer on the juction, the polysilicon layer on the first titanium silicide layer and the second titanium silicide layer on sidewalls of the contact hole.

7. The method as recited in claim 6, further comprising the steps of:
forming a metal layer on the polysilicon layer of the plug; and
forming a silicide layer as a second ohmic contact layer on the polysilicon layer of the plug by carrying out a second thermal treatment.

8. The method as recited in any one of claim 7, wherein the first and the second thermal treatments is carried out at a temperature of 600˜1,000° C.

9. The method as recited in claim 7, wherein the metal layer tantalum, and the silicide layer is a tantalum silicide layer.

10. The method as recited in claim 6, wherein TiOₓ is contained in the first titanium silicide layer.
